(19) United States
(12) Patent Application Publication
(10) Pub. No.: US 2023/0093604 A1
(43) Pub. Date: Mar. 23, 2023

(54) PHASE-CHANGE MEMORY WITH EMBEDDED AIR GAP

(71) Applicant: International Business Machines Corporation, Armonk, NY (US)

(72) Inventors: Injo Ok, Loudonville, NY (US); Soon-Cheon Seo, Glenmont, NY (US); Alexander Reznicek, Troy, NY (US); Youngseok Kim, Upper Saddle River, NJ (US)

(21) Appl. No.: 17/480,376

(22) Filed: Sep. 21, 2021

(51) Int. Cl. H01L 45/00

(52) U.S. Cl. CPC H01L 45/126; H01L 45/06; H01L 45/16

(57) ABSTRACT

A phase-change memory cell comprises a heater element. The heater element comprises a first resistive material, a conductive material, and a second resistive material. The first resistive material, second resistive material, and conductive material together form a well. The phase-change memory cell also comprises a deposition of dielectric material plugs the well, and an insulator gap within the well that is enclosed by the first resistive material, the conductive material, and the second resistive material.

### BACKGROUND

The present invention relates to phase-change memory, and more specifically, to phase-change memory with thermal isolation.

Phase-change memory is a type of random access memory that can be used to store bits of information based on the phase in which the memory is configured. Typical phase-change memory can be configured into a crystalline state (also referred to as a crystalline “phase”) and an amorphous state (also referred to as an amorphous “phase”). The information stored by a phase-change-memory cell (e.g., a logical “0” or a logical “1”) is typically determined by whether the cell is in the crystalline state or the amorphous state.

A phase-change-memory cell can typically be switched between the crystalline state and amorphous state by heating the cell with pre-determined heating patterns. Thus, typically phase-change-memory cells include a heater element located near the phase-change material in the cell. Passing current between two electrodes and through this heater element causes heat to be produced and spread to other portions of the cell. That heat can cause the phase-change material to change between amorphous and crystalline states.

### SUMMARY

Some embodiments of the present disclosure can be illustrated as a memory cell. The memory cell may comprise a first electrode and a second electrode. The first electrode may be embedded in a dielectric layer. The memory cell may also comprise a phase-change material. The phase-change material may be electrically between the first electrode and the second electrode. The memory cell may also comprise an active heater element. The active heater element may be electrically between the phase-change material and the first electrode. The active heater element may comprise a first resistive material that extends from the first electrode towards the phase-change material. The memory cell may also comprise a first insulator gap enclosed by the first resistive material.

Some embodiments of the present disclosure can also be illustrated as a method of forming a heater element with an enclosed insulator gap. The method may comprise depositing a set of hard masks on a dielectric layer. The method may then comprise etching a well through the set of hard masks and into the dielectric layer. The method may then comprise depositing a resistive material in the well. The method may then comprise depositing a dielectric material at the surface of the well from a first direction and depositing the dielectric material at the surface of the well from a second direction. The second direction and first direction may be opposite directions. Depositing the dielectric material from the second direction may plug the well.

Some embodiments of the present disclosure can also be illustrated as a memory module. The memory module may comprise a phase-change-memory cell with a set of heater elements. Each heater element in the set may comprise a first resistive material, a conductive material, and a second resistive material. The first resistive material, conductive material, and second resistive material may together form a well. Each heater element may also comprise a deposition of dielectric material that plugs the well. Each heater element may also contain an insulator gap within the well and enclosed by the first resistive material, the conductive material, and the second resistive material.

### BRIEF DESCRIPTION OF THE DRAWINGS

FIG. 1 depicts a cross section of a phase-change-memory cell with an insulator gap embedded within a heater element.

FIG. 2 depicts a cross section of a phase-change-memory cell with an active heater element and two inactive heater elements with embedded insulator gaps.

FIG. 3A depicts a cross-section of a first phase-change-memory cell before application of a projection liner.

FIG. 3B depicts a top-down view of the first phase-change-memory cell before application of the projection liner.

FIG. 3C depicts a top-down view of the first phase-change-memory cell after application of the projection liner.

FIG. 4A depicts a top-down view of a second phase-change-memory cell before application of the projection liner.

FIG. 4B depicts a top-down view of the second phase-change-memory cell after application of the projection liner.

FIG. 5A depicts a top-down view of a third phase-change-memory cell before application of the projection liner.

FIG. 5B depicts a top-down view of the third phase-change-memory cell after application of the projection liner.

FIG. 6A depicts a cross-section of a first stage of forming a phase-change-memory cell with an embedded insulator gap in accordance with embodiments of the present disclosure.

FIG. 6B depicts a cross-section of a second stage of forming the phase-change-memory cell with the embedded insulator gap in accordance with embodiments of the present disclosure.

FIG. 6C depicts a cross-section of a third stage of forming the phase-change-memory cell with the embedded insulator gap in accordance with embodiments of the present disclosure.

FIG. 6D depicts a cross-section of a fourth stage of forming the phase-change-memory cell with the embedded insulator gap in accordance with embodiments of the present disclosure.

FIG. 6E depicts a cross-section of a fifth stage of forming the phase-change-memory cell with the embedded insulator gap in accordance with embodiments of the present disclosure.

FIG. 6F depicts a cross-section of a sixth stage of forming the phase-change-memory cell with the embedded insulator gap in accordance with embodiments of the present disclosure.

FIG. 6G depicts a cross-section of a seventh stage of forming the phase-change-memory cell with the embedded insulator gap in accordance with embodiments of the present disclosure.

FIG. 6H depicts a cross-section of an eighth stage of forming the phase-change-memory cell with the embedded insulator gap in accordance with embodiments of the present disclosure.

FIG. 6I depicts a cross-section of a ninth stage of forming the phase-change-memory cell with the embedded insulator gap in accordance with embodiments of the present disclosure.

FIG. 6J depicts a cross-section of a tenth stage of forming the phase-change-memory cell with the embedded insulator gap in accordance with embodiments of the present disclosure.

### DETAILED DESCRIPTION

Phase-change memory (sometimes referred to herein as “PCM”) is a class of non-volatile random access memory. Like typical random-access memory, PCM cells can be switched between two states to code information. As such, typical PCM cells can code 1 bit of information, typically expressed in the form of a logical “0” or a logical “1.”

The information encoded by a PCM cell depends on the configuration (also referred to as the “state”), of that cell. Specifically, a PCM cells can be switched to a “SET” configuration to code a first logical value (e.g., a logical 0) or a “RESET” configuration to code a second logical value (e.g., a logical 1). In a SET configuration, a phase-change material (e.g., germanium-antimony-tellurium) in the PCM cell is in a crystalline format. In the crystalline format, the electrical conductivity of the phase-change material is relatively high. In a RESET configuration, however, a portion of the phase-change material in the PCM cell is reconfigured into an amorphous format. Further, in the amorphous format, the electrical conductivity of the phase-change material is relatively low.

Because the phase-change material is typically located between a bottom electrode and a top electrode of the PCM cell, switching between the SET and RESET states affects the ease with which electrical signals can travel between the first and second electrodes. This difference can be detected when reading from the cell, which enables identification of the cell's state. This state can be used to derive the information encoded by the cell.

Typical phase-change materials located in PCM cells can be switched between crystalline and amorphous states by heating the phase-change materials in a particular pattern. For example, heating a portion of phase-change material that is in an amorphous state with long, low-heat pulses can raise the temperature of the phase-change material to a temperature at which the phase-change material becomes crystalline (sometimes referred to herein as the “crystalline temperature”). A portion of that crystalline phase-change material can then be heated with short, high-heat pulses, which may rapidly increase the temperature of the material. If those pulses are terminated before the crystalline temperature is reached, the temperature of the material may rapidly cool. The portion of the phase-change material that rapidly cooled may settle in an amorphous state as a result.

To enable heat delivery to a phase-change material, typical PCM cells incorporate a heater element electrically between an electrode and the phase-change material. The heater element may include, for example, tantalum nitride (sometimes referred to herein as “TaN”), a metal alloy with a low electrical conductivity. Due to its low electrical conductivity, TaN tends to convert a relatively large amount electrical current that passes through it to heat energy. Thus, by creating a voltage between two electrodes (e.g., a bottom electrode and top electrode) that causes current to pass through a portion of TaN in the memory cell, heat can be produced. Of note, when an element, such as a heater element, is positioned such that a voltage induced between two other elements (e.g., a bottom electrode and a top electrode) causes a current to flow though that first element, that first element may be described herein as “electrically between” the two other elements.

Thus, if a heater element is electrically between two electrodes, a voltage induced between those two electrodes causes the heater element to generate heat in that heater element. Further, if the heater element is located near a phase-change material, that generated heat may be transferred to the phase-change material. This transfer of heat can be utilized to switch the state of a portion of the phase-change material between phases.

In some use cases, increasing the current that flows through a heater element can cause heat to generate more quickly in the heater element. This faster heat generation can in turn cause a phase-change material to change phases faster, enabling faster switching of the PCM cell between memory states. In many use cases, faster switching of phase-change memory may be very beneficial. For example, large and complex artificial intelligence networks utilize phase-change memory due to its fast-switching capabilities.

However, some RAM memory modules include components that are sensitive to frequent, or even single exposures to high current. These components may be damaged by currents that are sufficiently high to switch PCM cells at optimal speed. Thus, there exists a need to reduce the current necessary to switch PCM cells between states.

Further, some PCM cells exhibit poor heat-delivery efficiency. In these PCM cells, a non-negligible amount of heat generated by a heater element may spread to other portions of the PCM cell before it is able to heat the phase-change material. For example, generated heat in some PCM cells can spread backwards from the phase-change material, through the heater element, and back to the bottom electrode. Similarly, heat can also spread from a portion of the phase-change material (typically a dome of amorphous phase material) into the surrounding dielectric, which can then spread down through the cell towards the bottom electrode.

Unfortunately, this waste heat effectively increases the current required to heat a phase-change material in the cell, because some of the heat created as a result of the current does not significantly heat the phase-change material. In other words, low heat-delivery efficiency requires more current be passed through the memory module than would be needed if the PCM cells in the module had high heat-delivery efficiency. This creates an obstacle to operating PCM modules at optimal efficiency for high-performance use cases.

Some PCM modules incorporate insulating elements in an attempt to reduce waste heat, and thus to increase the efficiency of heat delivery to the phase-change material. For example, some PCM cells incorporate air or vacuum gaps between components of the PCM cell in order to slow the spread of generated heat through the cell. However, issues in the designs of these insulating elements often significantly reduces their effectiveness. Thus, a need exists for increasing the heat-delivery efficiency of heater elements in PCM cells.

Some embodiments of the present disclosure address the above-described issues by enclosing an insulator gap within the heater element of a PCM cell. For example, some embodiments of the present disclosure disclose a heater element that takes the form of a hollow cylinder of resistive material. This resistive material may, for example, be a metal alloy with relatively low electrical conductivity. During formation of the PCM cell, the hollow cylinder may be plugged to prevent the cylinder from being filled during later stages of formation (for example, with projection liner material or phase-change material). Thus, an air gap may be enclosed within the heater element, which may reduce the spread of heat from the phase-changing material to an electrode through the heater element.

Thus, in some use cases, enclosing an air gap within a heater element that is configured to generate and deliver heat to a phase-change material (sometimes referred to herein as an “active heater element”) may significantly reduce the loss of generated heat back through a heater element. However, in some use cases, generated heat may still be lost through other pathways within a PCM cell. For example, heat from a portion of phase-change material that is in an amorphous phase may be transferred from that amorphous phase to a dielectric material in which the active heater element is embedded and with which the amorphous phase interfaces.

For this reason, some embodiments of the present disclosure also incorporate one or more inactive heater elements in a PCM cell addition to an active heater element. These inactive heater elements may resemble the active heater element in that they also enclose an air gap. However, the inactive heater elements may not physically interface with an electrode and thus may not be electrically connected to an electrode or electrically between an electrode and the phase-change material of the cell. For this reason, the inactive heater elements may not function to generate heat or spread heat to the phase-change material. Rather, the inactive heater elements may resemble extra heater elements that function only to provide insulation.

Further, the inactive heater elements may be embedded within the same layer of dielectric material within which the active heater element is embedded and on which the phase-change material is formed. For this reason, the insulation provided by the inactive heater elements may reduce the heat that is able to spread from the phase-change material back through that dielectric layer.

Finally, some embodiments of the present disclosure may leverage the added insulation provided by a set of inactive heater elements in order to increase the ability of current (e.g., a read signal) to travel between a bottom electrode and a top electrode when the PCM cell is in a RESET state. For example, some embodiments may form a projection liner not only over an active heater element, but over the active heater element and a set of inactive heater elements. The insulation from the inactive heater elements may reduce heat that is able to spread from the projection liner to the dielectric material in which the inactive heater elements are embedded. However, incorporating a larger-than-standard projection liner may enable a read signal to easily pass from a first electrode, through the active heater element, into the projection liner, and around an amorphous portion of the phase-change material. Thus, the state of the PCM cell may still be read in use cases in which the amorphous phase of the phase-change material is particularly non conductive to electrical signals and in instances in which the amorphous portion of the phase-change material is particularly large.

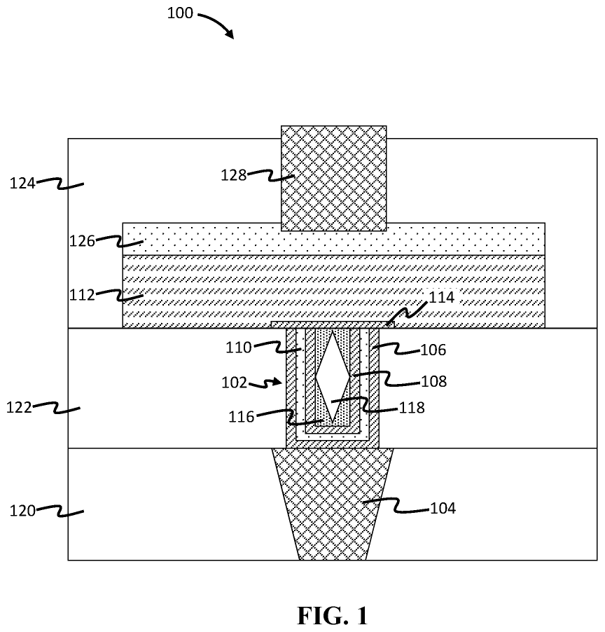

FIG. 1 depicts a cross section of a phase-change-memory cell 100 (also referred to herein as “PCM cell 100”) with an insulator gap embedded within a heater element 102 that is formed on an electrode 104. Heater element contains a first resistive material 106 and a second resistive material 108. These materials may be composed of a material that has a relatively low electrical conductivity, such that current that passes from electrode 104 into the resistive materials 106 and 108 cause the resistive materials to heat up due to their resistivity to the electric current. Examples of potential resistive materials include carbon, tantalum nitride (TaN), tantalum carbide (TaC), tungsten nitride (WN), tungsten carbide (WC), and tantalum silicon nitride (TaSiN). Potential resistive materials could also include insulators or high-resistive metal oxides such as hafnium oxide (HfO₂), Al₂O₃, ZrO₂, SiN, and SiO₂. Of note, resistive material 106 and 108 could be composed of the same material, or could be composed of different materials.

Heater element 102 also contains a conductive material 110 located spatially between resistive materials 106 and 108. This conductive material may serve to conduct generated heat from heater element 102 to phase-change material 112. Phase-change material 112 may be, for example, germanium-antimony-tellurium (GST), GeTe, Sb₂Te₃, or TiTe.

Specifically, current that originates in electrode 104 may pass into resistive material 106. The relatively high resistivity of resistive material 106 causes heat to be generated as a result of this current. This heat may then transfer to conductive material 110. Due to the relatively low resistivity of conductive material 110, this heat may spread quickly through conductive material 110 and into phase-change material 112.

Of note, an entity being “spatially between” another pair of entities, as used herein, may not necessarily refer to that entity being located on a straight line that intersects the pair of entities. Rather, some instances of “spatially” between may refer to an entity that is “between” two other entities in a single dimension. For example, a first entity that is below a second entity in a height dimension and above a third entity in that height dimension may be considered “spatially between” the second and third entity, even if it is located no where near those two entities in a horizontal dimension.

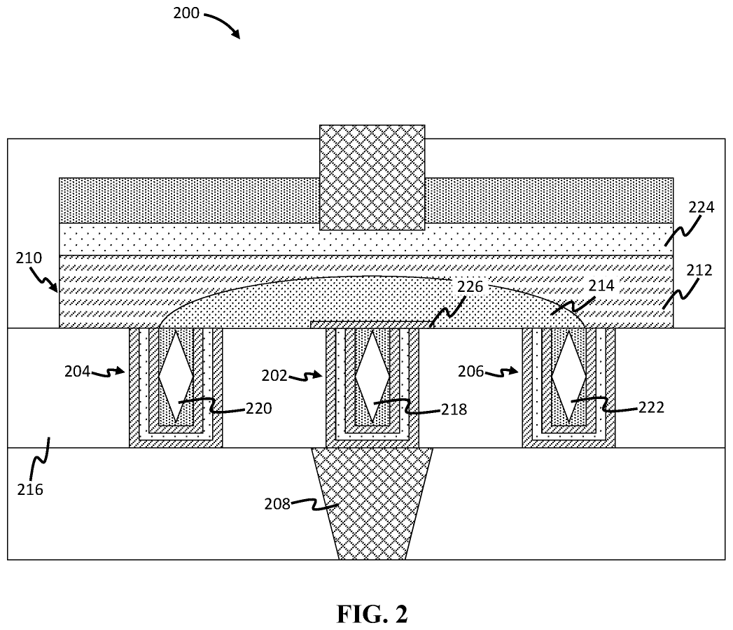

As illustrated, a projection liner 114 has been formed over heater element 102, and is thus located spatially and electrically between heater 102 and phase-change material 112. Projection liner 114 may be formed of similar materials as resistive materials 106 and 108. Projection liner 114 may increase the ability of a read signal to travel from electrode 104 and through phase-change material 112 when PCM cell is in a RESET configuration. This is elaborated upon in FIGS. 2, 3A-3C, 4A-4B, and 5A-5B.

Of note, the relatively high resistivity of resistive material 108 may both cause any current that passes through resistive material 108 to generate heat, but also to prevent the heat that spreads to conductive material 110 from spreading to the center of heater element 102. In other words, the heat that spreads to conductive material 110 may be more likely to spread to phase-changing material 112.

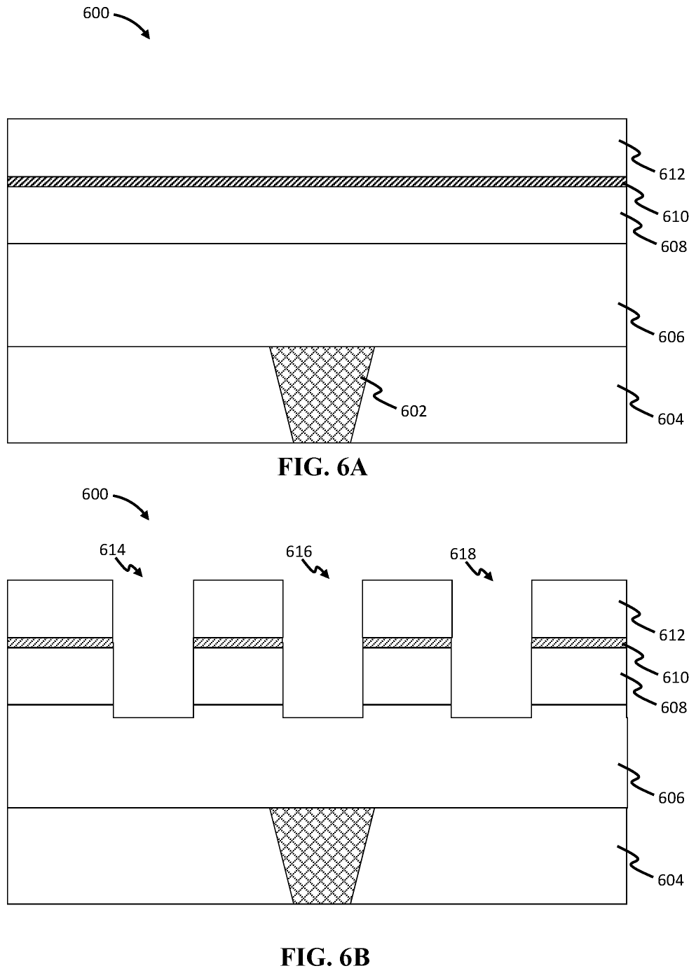

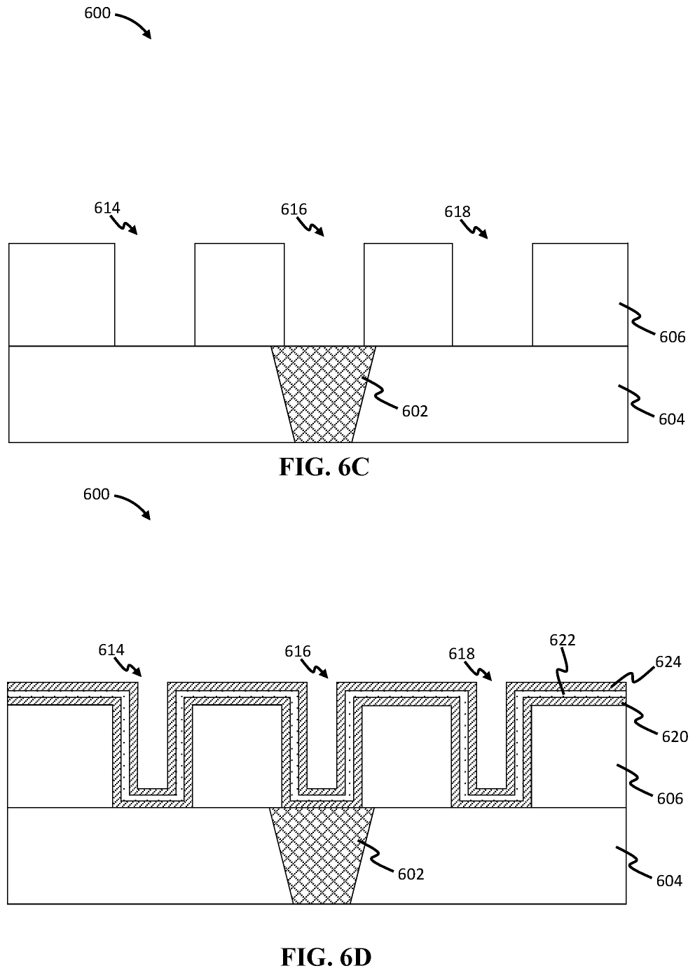

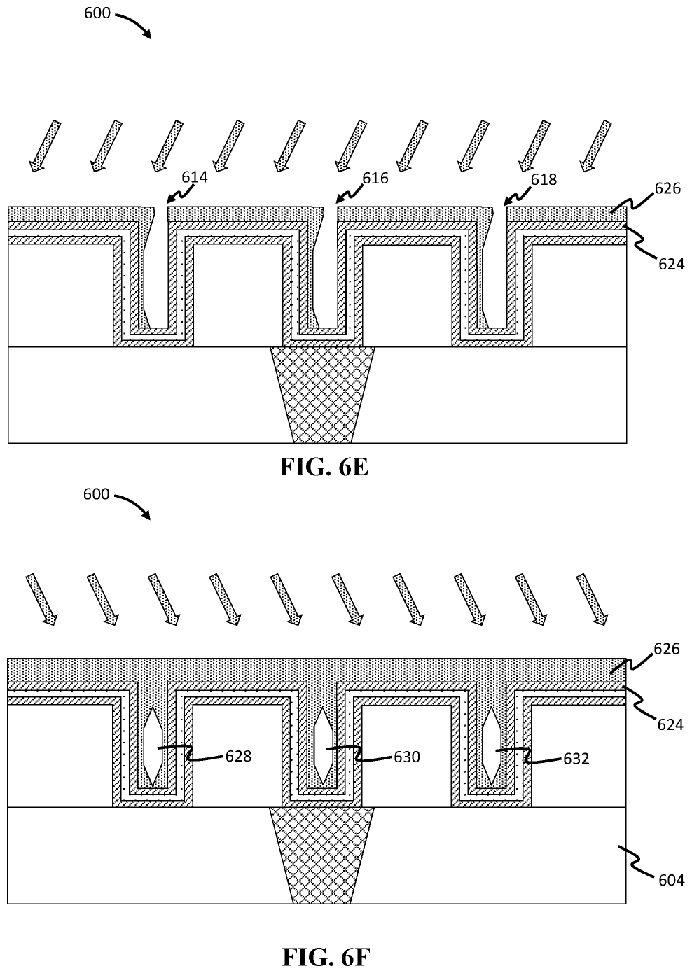

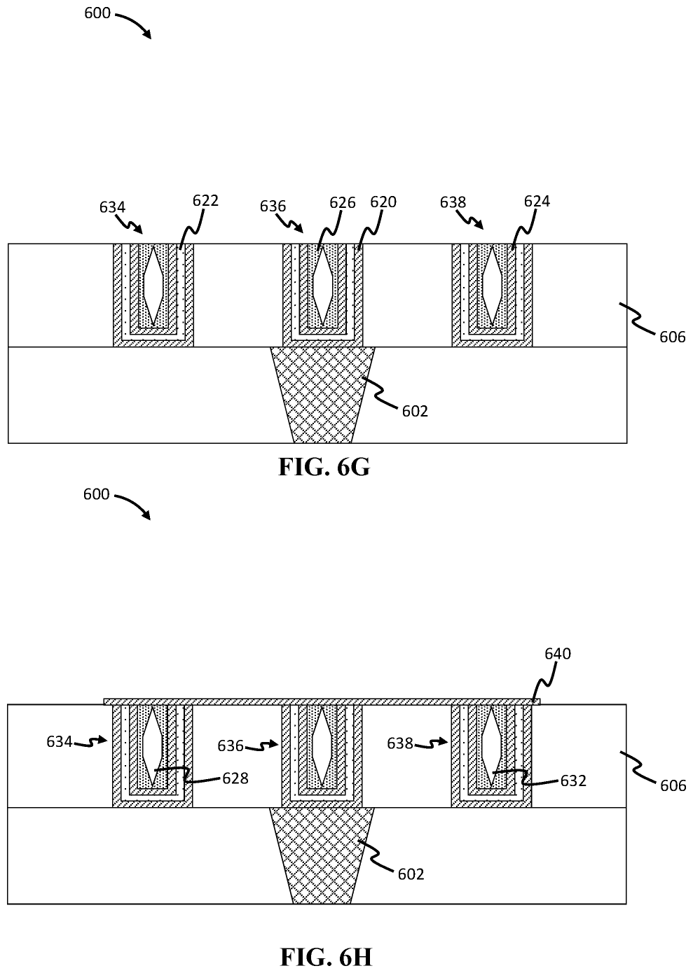

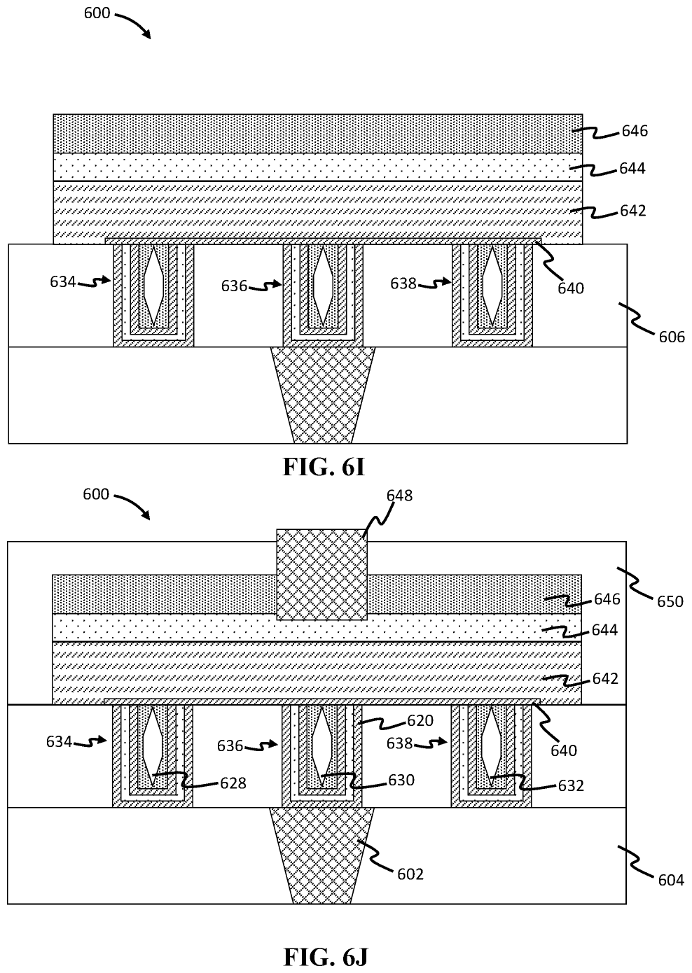

Heater element 102 also contains a filler material 116 (e.g., a dielectric) that partially fills the gap between the inner walls of resistive material 108. Filler material 116 may have been applied through several depositions that together plugged the gap between the inner walls of resistive material 108 before the gap was completely filled, as discussed in connection with FIGS. 6F and 6G. As a result, heater element 102 also contains an insulator gap 118 that is enclosed by resistive materials 106 and 108, conductive material 110, and filler material 116. The composition of insulator gap 118 may depend upon the environment in which PCM cell 100 was formed. For example, if PCM cell 100 were formed in air, insulator gap 118 may take the form of an air gap. If PCM cell 100 were formed in a vacuum chamber, however, insulator gap 118 may be empty space (a vacuum) that may also contain a trace amount of gaseous material that sublimates from filler material 116.

Because FIG. 1 depicts a cross section of PCM cell 100, the three-dimensional shape of heater element 102 may vary. For example, heater element 102 may take the form of a cylinder, such that it appears as a circle when viewed from the top down. In theory, heater element 102 may also take the form of a cuboid, such that it appears as a square or other rectangle when viewed from the top down. Other shapes are also possible, provided that they enable heater element 102 to enclose insulator gap 118.

PCM cell 100 is also illustrated as containing dielectric layers 120, 122, and 124. Dielectric layers 120, 122, and 124 may be patterned using, for example, silicon nitride (sometimes referred to herein as “SiN”), or tetraethyl orthosilicate (sometimes referred to herein as “TEOS”). Dielectric layer 122, being spatially between dielectric layers 120 and 124, may be a different dielectric material than dielectric layers 120 and 124. Further, because heater element 102 is embedded within dielectric layer 122, and because dielectric layer 122 separates phase-change material 112 from electrode 104, it may be beneficial to pattern dielectric layer 122 with a dielectric material with a relatively high thermal resistance. This may help to add insulation to PCM cell 100, preventing the spread of heat towards electrode 104.

PCM cell 100 also includes conductive layer 126 and electrode 128. Electrode 128 may be used in conjunction with electrode 104 to create a voltage across PCM cell 100, causing a current to tend to flow through heater element 102, phase-change material 112, and conductive material 126. Conductive material 126 may be composed of a material with a relatively high electrical conductivity, such as TiN. Conductive material 126 is patterned on top of phase-change material 112, and electrically between phase-change material 112 and electrode 128 to encourage current flowing through PCM cell 100 to flow into electrode 128, rather than into surrounding structures.

FIG. 2 depicts a cross section of PCM cell 200 with an active heater element 202 and two inactive heater elements 204 and 206 with embedded insulator gaps. As illustrated, active heater element 202 resembles heater element 102 of FIG. 1 for the purpose of understanding. However, it is of note that they need not be identical designs; some properties of active heater element 202 may differ slightly from heater element 102 while still keeping within the scope and spirit of this disclosure.

Active heater element 202 is considered an “active” heater element because it interfaces with bottom electrode 208 and is electrically between bottom electrode 208 and phase-change material 210. Of note, as illustrated in FIG. 2, PCM cell 200 is in a RESET state, and thus phase-change material 204 exhibits a crystalline portion 212 and an amorphous portion 214. Amorphous portion 214 is in the shape of a dome that originated from a location near active heater element 202. This dome shape may often be referred to as a mushroom cell.

In typical phase-change materials, such as GST, an amorphous portion typically has far lower thermal and electrical conductivity than a crystalline portion. Thus, in many embodiments amorphous portion 214 may have far lower thermal conductivity than crystalline portion 212. For this reason, heat that spreads to amorphous portion 214 from active heater element 202 may slowly spread through amorphous portion 214, during which time it may have a tendency to spread downward into dielectric layer 216. This may occur, for example, during formation of the mushroom cell when transitioning from a SET state to the RESET state or when heating amorphous portion 214 to transition from the RESET state back to the SET state. In either instance, this heat loss may result in more heat overall being required to transition the state of PCM 200, which in turn requires more current to flow through the overall memory module.

For these reasons, inactive heater elements 204 and 206 are also embedded within dielectric layer 216. As illustrated, these heater elements have been formed such that they do not interface with bottom electrode 208 and are not electrically between bottom electrode 208 and phase-change material 210. For this reason inactive heater elements 204 and 206 do not receive non-negligible amounts of current from bottom electrode 208, and thus do not participate in heating phase-change material 210. Because of this, they are referred to as “inactive.”

However, inactive heater elements 204 and 206 otherwise structurally resemble active heater element 202. Specifically, all of active heater element 202 and inactive heater elements 204 and 206 all contain insulator gaps 218, 220, and 222. For this reason, inactive heater elements 204 and 206 may contribute to insulating dielectric layer 216 and electrode 208 from heat that spreads to amorphous portion 214. In other words, inactive heater elements 204 and 206 reduce heat loss by reducing unwanted heat spreading from the mushroom cell.

As illustrated in FIG. 2, inactive heater elements 204 and 206 are positioned such that insulator gaps 220 and 222 are directly beneath the periphery of amorphous portion 214. However, in some embodiments it may be beneficial to place inactive heater elements 204 and 206 in slightly different positions. For example, if inactive heater elements 204 and 206 were positioned closer to active heater element 202, they may be more effective at preventing heat from spreading from amorphous portion 214 into dielectric layer 216. Further, in some embodiments it may be beneficial to include more inactive heater elements that are not pictured here.

These factors, however, may depend on the use case. For example, the most optimal location for insulation in dielectric layer 216 may depend upon, for example, the dimensions, structure, and material properties of active heater 202, the dimensions and material properties phase-change material 210, and the dimensions and material properties of conductive layer 224. Further, in some use cases restrictions on the process by which PCM cell 200 is formed may prevent inactive heater elements 204 and 206 from being formed closer to active heater element 202. Thus, the precise desired locations and numbers of inactive heater elements in a PCM cell may depend upon the circumstances of the use case.

PCM 200 also contains a projection liner 226. Projection liner 226 may be included in PCM 200 to provide a path for read-voltage signals to pass through amorphous portion 214. However, as illustrated, projection liner 226 is significantly narrower than amorphous portion 214, and thus may not be as effective as desired. Unfortunately, in many typical PCM cells, the size of projection liners is limited to prevent a conduit for heat to spread back toward the bottom electrode. Specifically, because typical projection liners are more thermally conductive than the amorphous portions of phase-change materials, they can act as heat sinks for heat that does not readily spread to the amorphous portions. This heat may leak into the dielectric layer on which the projection liner is formed (here, dielectric layer 216), resulting in heat loss.

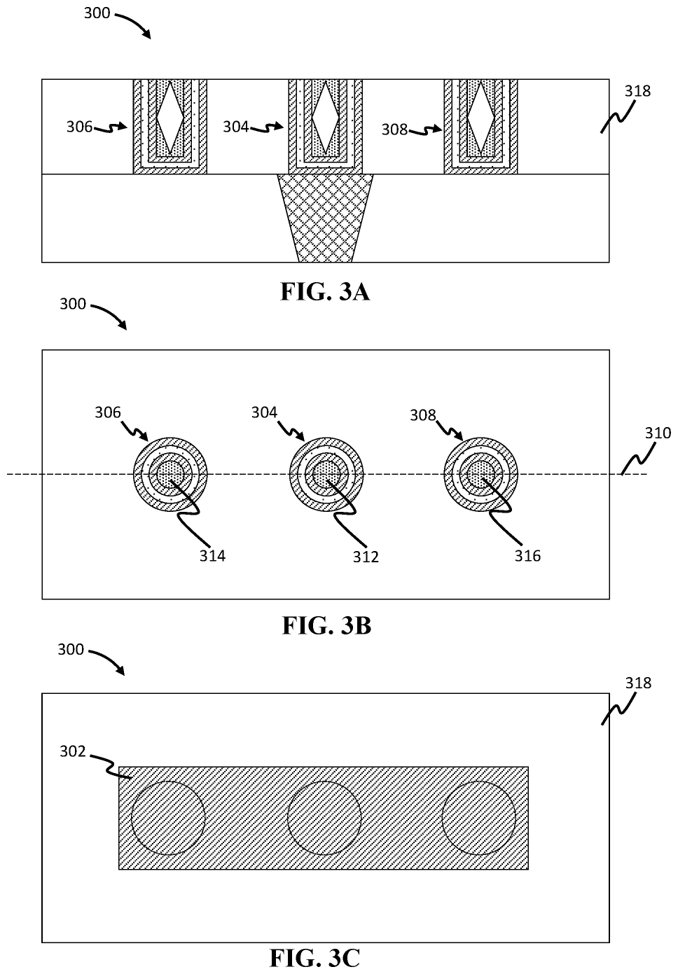

However, in some embodiments of the present disclosure, the dimensions of a projection liner can be increased significantly without an unacceptable risk of heat loss. This may be due to the number and position of inactive heater elements in those embodiments. This concept, together with the concept of adjusting the number and position of inactive heater elements, is explored in FIGS. 3A-3C, 4A-4B, and 5A-5B.

FIG. 3A depicts a cross-section of PCM cell 300 before application of projection liner 302. PCM cell 300, like PCM cell 200, is illustrated with one active heater element 304 and a set of two inactive heater elements 306 and 308. The positions and numbers of inactive heater elements 306 and 308 may have been selected based on the circumstances of the use case in which PCM cell 300 is likely to be used, as discussed with respect to FIG. 2.

FIG. 3B depicts a top-down view of PCM cell 300 before application of projection liner 302. As illustrated in FIG. 3B, the set of inactive heater elements 306 and 308 are arranged in a line segment with active heater element 304. This may also be described herein, for example, as active heater element 304 and inactive heater elements 306 and 308 being in a set of heater elements that are arranged in a line segment.

FIG. 3B contains perspective indicator 310, illustrated by a dotted line. Perspective indicator 310 indicates the plane in FIG. 3B that the cross-section view of FIG. 3A depicts. As such, FIG. 3B depicts active heater element 304 and inactive heater elements 306 and 308 as having a cylindrical shape, however other designs of heater elements are theoretically possible.

Of note, FIG. 3B illustrates that active heater element 304 and inactive heater elements 306 and 308 contain plugs 312, 314, and 316. These plugs may be composed of a dielectric material such as SiN, and may seal insulator gaps within the heater elements.

FIG. 3C depicts a top-down view of PCM cell 300 after application of projection liner 302. As illustrated, projection liner 302 has been formed to match the arrangement of active heater element 304 and inactive heater elements 306-308. In other words, projection liner 304 is formed as a line segment on top of the heater elements. For this reason, the spread of heat from projection liner 302 to dielectric layer 318 may be reduced.

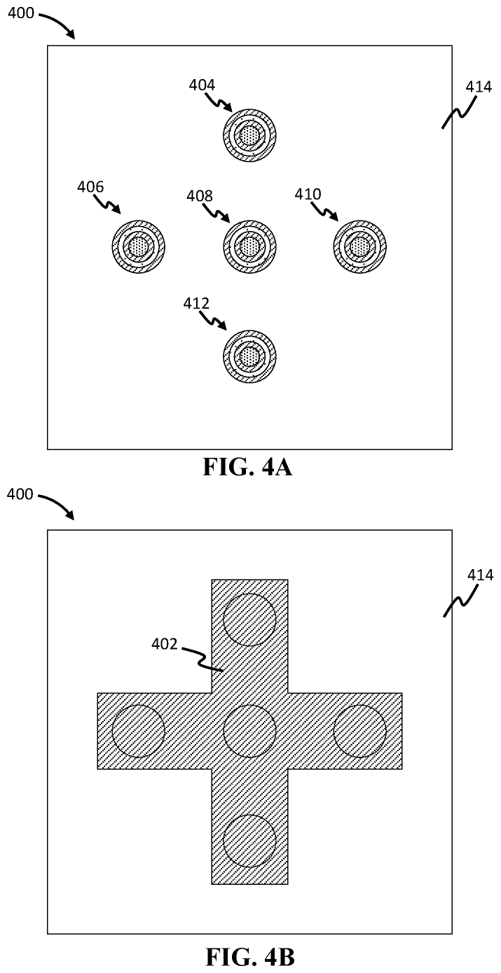

FIG. 4A depicts a top-down view of PCM cell 400 before application of projection liner 402. PCM cell 400 contains a set of heater elements 404-412 that are embedded within dielectric layer 414 and arranged in the shape of a plus sign. In some embodiments, heater element 408 may be an active heater element, whereas heater elements 404, 406, 410, and 412 may be inactive heater elements. In this orientation, the set of inactive heater elements may provide particularly effective insulation for dielectric 414 from heat that spreads from heater element 408 in a phase-change material (or projection liner 402) in two axes: the axis that intersects heater elements 404 and 412 and the axis that intersects heater elements 406 and 410.

FIG. 4B depicts a top-down view of PCM cell 400 after application of projection liner 402. Similar to projection liner 302 of FIG. 3C, projection liner 402 has been formed to match the arrangement of the set of heater elements 404-412. As such, projection liner 402 is arranged in the shape of a plus sign.

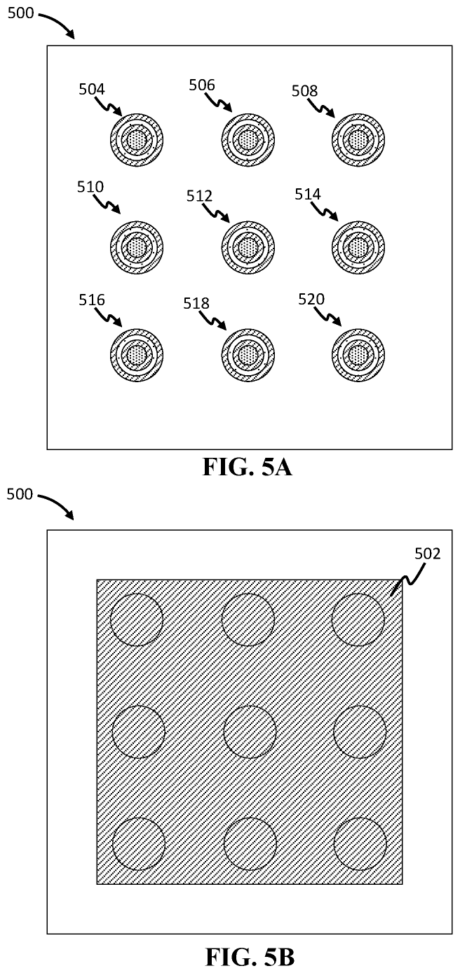

FIG. 5A depicts a top-down view of PCM cell 500 before application of projection liner 502. PCM cell 500 contains a set of heater elements 504, 506, 508, 510, 512, 514, 516, 518, and 520. Set of heater elements 504-520 are arranged in the shape of a rectangular grid (specifically, a square rectangular grid). In some embodiments, heater element 512 may be an active heater element, and heater elements 504-510 and 514-520 may be inactive heater elements. In this orientation, the inactive heater elements would surround the active heater element, insulating the dielectric in which they are embedded from heat that spreads from heater element 512 and through a phase-change material (or projection liner 502) in 360 degrees, but in particular in 4 axes: the axis that intersects heater elements 506 and 518, the axis that intersects heater elements 510 and 514, the axis that intersects heater elements 504 and 520, and the axis that intersects heater elements 508 and 516.

FIG. 5B depicts a top-down view of PCM cell 500 after application of projection liner 502. Similar to projection liners 302 and 402, projection liner 502 has been formed to match the arrangement of the set of heater elements 504-520. As such, projection liner 502 is arranged in the shape of a square.

Of note, while only four arrangements of heater elements are illustrated by FIGS. 1-5B, some embodiments of the present disclosure may feature other arrangements of heater elements that are otherwise within the scope and spirit of this disclosure.

FIGS. 6A-6J depict the major stages of a process of forming a phase-change memory cell 600 with inactive heater elements and a projection liner that matches the arrangement of the cell's heater elements, in accordance with embodiments of the present disclosure.

FIG. 6A depicts a cross-section of a first stage of PCM cell 600. In FIG. 6A, PCM cell 600 includes a first electrode 602 embedded in a first dielectric layer 604, a second dielectric layer 606, and hard-mask layers 608, 610, and 612. Hard mask 608 could be, for example, an organic planarization layer. Hard mask 610 could be, for example, a silicon antireflective coating. Hard mask 612 could be, for example, a photoresist layer. This first stage of formation incorporates 3 layers of hard mask, other hardmask organizations are possible. For example, a 4-layer hardmask could be formed by splitting hard mask 610 into two hardmasks, such as a bottom antireflective coating and silicon oxynitride.

FIG. 6B depicts a cross-section of a second stage of forming PCM cell 600 with three embedded insulator gaps in accordance with embodiments of the present disclosure. In FIG. 6B, hard masks 608-612 have been etched through (for example, through reactive ion etching) in a selective etching process. This has resulted in three wells 614-618 that extend into dielectric layer 606. The amount to which wells 614-618 extend into dielectric layer 606 may depend, for example, on the etching process used and the relative dimensions of dielectric layer 606 and hardmask layers 608-612.

FIG. 6C depicts a cross-section of a third stage of forming PCM cell 600 with three embedded insulator gaps in accordance with embodiments of the present disclosure. In FIG. 6C, hard masks 608-612 have been removed through non-selective etching process. Further, wells 614-618 have been deepened into dielectric layer 606, causing them to reach electrode 602 and dielectric layer 604. In this stage, wells 614-618 provide an area in which heater elements can begin to form.

FIG. 6D depicts a cross-section of a fourth stage of forming PCM cell 600 with three embedded insulator gaps in accordance with embodiments of the present disclosure. In FIG. 6D, a layer of a resistive material 620 (also referred to herein as a heat-generating material), such as tantalum nitride (TaN), tantalum carbide (TaC), and tantalum silicon nitride (TaSiN), is deposited on dielectric layer 606 and in wells 614-618. Of note, resistive material 620 is also deposited onto electrode 602, forming an electrical connection. Conductive material 622, such as titanium nitride (TiN), titanium carbide (TiC), and titanium silicon nitride (TiSiN), is deposited on top of resistive layer 620. Finally, a second layer resistive material 624 is then formed on top of conductive material 622.

FIG. 6E depicts a cross-section of a fifth stage of forming PCM cell 600 with three embedded insulator gaps in accordance with embodiments of the present disclosure. FIG. 6E depicts a first stage of plugging wells 614-618 with dielectric material 626 to enclose an insulator gap. Specifically, FIG. 6E depicts an angular deposition of dielectric, such as SiN, over the entirety of the illustrated portion of PCM cell 600. For example, FIG. 6E may depict a chemical vapor deposition of SiN. Due to the angle of deposition and dimensions of wells 614 and 618, dielectric has begun to form within each well with incomplete coverage. Specifically, much of dielectric has built up on the top-left corner of the surface of each well at the corner of resistive layer 624. As a result, a greater portion of dielectric material 626 has gathered at the opening of each well than inside each well.

FIG. 6F depicts a cross-section of a sixth stage of forming PCM cell 600 with three embedded insulator gaps in accordance with embodiments of the present disclosure. FIG. 6F depicts a second stage of plugging wells 614-618 with dielectric material 626 to enclose insulator gaps 628, 630, and 632. In practice, the shapes of insulator gaps 628, 630, and 632 may vary based on the angle of depositions and dimensions of wells 614-618.

FIG. 6F depicts an angular deposition of the same dielectric as in FIG. 6E, but from the opposite direction. As used herein, “opposite” direction is not used to describe an exact relative angle (e.g., an angle of exactly 90 degrees less), but rather an angle that is on the opposite side of an angle that is approximately perpendicular to a plane on which PCM cell 600 is being formed.

For example, if an angle that is exactly perpendicular to the surface of dielectric layer 604 were considered to be 0 degrees and the deposition in FIG. 6E was from an angle of greater than 0 degrees (e.g., 45 degrees), the deposition in FIG. 6F would be from an opposite direction if it were from an angle of less than 0 degrees (e.g., −60 degrees). The exact angle of both depositions may be based, for example, on the dimensions of wells 614-618 and also the restrictions on the deposition process in a particular use case. The exact deposition angles may not be vital as long as they, together, result in dielectric material 626 plugging wells 614-618 in a way that creates insulator gaps 628-632.

FIG. 6G depicts a cross-section of a seventh stage of forming PCM cell 600 with three embedded insulator gaps in accordance with embodiments of the present disclosure. In FIG. 6G, the excess dielectric material 626, resistive material 624, conductive material 622, and resistive material 620 have been removed to the surface of dielectric layer 606. As a result, heater elements 634, 636, and 638 have been formed. As heater 636 has been formed on electrode 602, heater element 636 could be configured as an active heater element by depositing a phase-change material on or effectively on heater element 636.

FIG. 6H depicts a cross-section of an eighth stage of forming PCM cell 600 with three embedded insulator gaps in accordance with embodiments of the present disclosure. In FIG. 6H, projection liner 640 has been deposited upon dielectric layer 606 and heater elements 634, 636, and 638. In some embodiments, for example, this may involve depositing a projection liner over the entire top surface of PCM 600 and etching away the projection liner from the area beyond heater elements 634 and 648, as well as etching the depth of projection liner 640 to provide for deposition of a phase-change material, conductive layer, and dielectric layers in further stages of formation.

As previously discussed, projection liner 640 could take the form of a relatively resistive material, such as TaN, as long as that material has lower electrical resistivity than an amorphous phase of phase-change material to be used for PCM cell 600. Projection liner 640 may be significantly wider (as compared to the width of active heater 636) than in typical PCM cells. This may be possible, for example, because insulator gaps 628 and 632 in heater elements 634 and 638 may reduce the spread of heat from projection liner 640 into dielectric layer 606.

FIG. 6I depicts a cross-section of a ninth stage of forming PCM cell 600 with three embedded insulator gaps in accordance with embodiments of the present disclosure. In FIG. 6I, phase-change material 642 has been deposited upon projection liner 640 and dielectric layer 606. Phase-change material 642 may be composed of germanium-antimony-tellurium (sometimes referred to as GST), GeTe, Sb₂Te₃, TiTe, or some other elemental, binary, or ternary alloys of antimony, tellurium, and germanium. Conductive material 644 (e.g., TiN) has been formed on phase-change material 642, which may be useful for creating an electrically conductive path for current to flow between phase-change material 642 and an electrode. Finally, dielectric material 646 (e.g., SiN) has been deposited upon conductive material 644. This may be useful in preventing current from escaping conductive material 644 except through an electrode.

FIG. 6J depicts a cross-section of a tenth stage of forming PCM cell 600 with three embedded insulator gaps in accordance with embodiments of the present disclosure. In FIG. 6I, electrode 648 has been formed in PCM cell 600 such that it contact conductive material 644 and is embedded within dielectric material 646. Dielectric material 650 has also been deposited around electrode 648, phase-change material 642, conductive material 644, and dielectric material 646.

As illustrated in FIG. 6J, a voltage applied between electrodes 602 and 648 may cause current to flow between those two electrodes. That current may originate in PCM cell 600 at electrode 602 and enter heater element 636, an active heater element. That current may be used to heat heater element 636 due to the resistive property of resistive material 620. That heat may then spread through projection liner 640 to phase-change material 642, at which point it could cause a portion of phase-change material 642 (e.g., a mushroom cell) to change to an amorphous phase. Further voltages applied to between electrodes 602 and 648 may cause heat to spread to the amorphous portion to revert it to a crystalline phase. Because heater elements 634, 636, and 638 all have enclosed insulator gaps 628, 630, and 632, the spread of this heat from the amorphous portion to dielectric layer 604 or electrode 602 may be significantly reduced.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A memory cell comprising:
a first electrode and a second electrode, wherein the first electrode is embedded in a first dielectric layer;
a phase-change material electrically between the first electrode and second electrode;
an active heater element electrically between the phase-change material and the first electrode, wherein the active heater element comprises a first resistive material that extends from the first electrode towards the phase-change material; and
a first insulator gap enclosed by the first resistive material.

2. The memory cell of claim 1, further comprising:
a projection liner electrically between the active heater element and the phase-change material.

3. The memory cell of claim 1, further comprising:
an inactive heater element located spatially between the first electrode and the phase-change material, wherein the inactive heater element comprises a second resistive material that extends from the first dielectric layer towards the phase-change material;
a second insulator gap enclosed by the second resistive material.

4. The memory cell of claim 3, further comprising:
a projection liner, wherein the projection liner is located spatially between the active heater element and the phase-change material and spatially between the inactive heater element and the phase-change material.

5. The memory cell of claim 3, further comprising a second dielectric layer in which the active heater element and inactive heater element is embedded, and wherein the inactive heater element is part of a set of inactive heater elements that are arranged in a line segment with the active heater element in the second dielectric layer.

6. The memory cell of claim 1, further comprising a set of inactive heater element that are arranged in the shape of a plus sign with the active heater element.

7. The memory cell of claim 6, further comprising a projection liner that matches the arrangement of the set of inactive heater elements and the active heater element.

8. The memory cell of claim 1, wherein the active heater element further comprises:
a conductive material that extends from the first resistive material towards the phase-change material;
a second resistive material that extends from the conductive material towards the phase-change material;
wherein the conductive material and second resistive material also enclose the first insulator gap.

9. The memory cell of claim 1, wherein the insulator gap is a vacuum gap.

10. A method of forming a heater element with an enclosed insulator gap, the method comprising:
depositing a set of hard masks on a dielectric layer,
etching a well through the set of hard masks and into the dielectric layer;
depositing a resistive material in the well;
depositing a dielectric material at the surface of the well from a first direction; and
depositing the dielectric material at the surface of the well from a second direction, wherein the second direction and first direction are opposite directions;
wherein depositing the dielectric material from the second direction plugs the well.

11. The method of claim 10, further comprising:
depositing a conductive material in the well on the resistive material; and
depositing a second resistive material in the well on the conductive material.

12. The method of claim 11, further comprising selecting the first direction and the second direction based upon the dimensions of the well.

13. The method of claim 10, further comprising depositing a projection liner on the heater element, wherein the shape of the projection liner matches the arrangement of the heater element and a set of inactive heater elements.

14. The method of claim 10, wherein the depositing the dielectric material from the first direction and from the second direction is performed by chemical vapor deposition.

15. A memory module comprising:
a phase-change-memory cell, with a set of heater elements, wherein each heater element in the set of heater elements comprises:
a first resistive material;
a conductive material;
a second resistive material, wherein the first resistive material, conductive material, and second resistive material together form a well;
a deposition of dielectric material that plugs the well;
an insulator gap within the well and enclosed by the first resistive material, conductive material, and second resistive material.

16. The memory cell of claim 15, wherein the heater elements in the set of heater elements are arranged in a rectangular grid shape.

17. The memory cell of claim 15, wherein the heater elements in the set of heater elements are arranged in the shape of a plus sign.

18. The memory cell of claim 15, wherein the memory cell further comprises a projection liner with a shape that matches the arrangement of the set of heater elements.

19. The memory cell of claim 15, wherein the set of heater elements comprises at least one inactive heater element.

20. The method of claim 15, wherein the insulator gap is an air gap.
